(19) United States
(12) Patent Application Publication
(10) Pub. No.: US 2025/0316506 A1
(43) Pub. Date: Oct. 9, 2025

(54) SUBSTRATE PROCESSING METHOD AND SUBSTRATE PROCESSING SYSTEM

(71) Applicant: Tokyo Electron Limited, Tokyo (JP)

(72) Inventors: Keisuke SAKAGUCHI, Koshi City, Kumamoto (JP); Susumu HAYAKAWA, Kikuchi-gun, Kumamoto (JP)

(21) Appl. No.: 18/864,999

(22) PCT Filed: May 1, 2023
(86) PCT No.: PCT/JP2023/017025

§ 371 Date: Nov. 12, 2024

(30) Foreign Application Priority Data
May 13, 2022 (JP) 2022-079719

(51) Int. Cl. H01L 21/67; H01L 21/304

(52) U.S. Cl. CPC H01L 21/6708; H01L 21/304; H01L 21/67253

(57) ABSTRACT

A substrate processing method of processing a substrate includes grinding a first surface of the substrate to form, on the first surface, a recess portion whose center is more depressed than an outer peripheral portion thereof; measuring a thickness of the substrate after being ground, to acquire a thickness distribution of the substrate; calculating, based on the thickness distribution, an optimal etching condition for optimizing an etching amount deviation distribution when etching the first surface; and etching, under the optimal etching condition, the first surface of the substrate after being ground by supplying an etching liquid to the first surface from an etching liquid supply.

### TECHNICAL FIELD

The various aspects and embodiments described herein pertain generally to a substrate processing method and a substrate processing system.

### BACKGROUND

Patent Document 1 discloses a manufacturing method for a semiconductor wafer, including a process of flattening at least a surface of a wafer obtained by slicing a semiconductor ingot, and a process of etching the surface of the flattened wafer by spin etching.

### PRIOR ART DOCUMENT

Patent Document 1: Japanese Patent Laid-open Publication No. H11-135464

### DISCLOSURE OF THE INVENTION

### Problems to be Solved by the Invention

Exemplary embodiments provide a technique capable of appropriately controlling a surface shape of a substrate in an etching processing.

### Means for Solving the Problems

In an exemplary embodiment, a substrate processing method of processing a substrate includes grinding a first surface of the substrate to form, on the first surface, a recess portion whose center is more depressed than an outer peripheral portion thereof; measuring a thickness of the substrate after being ground, to acquire a thickness distribution of the substrate; calculating, based on the thickness distribution, an optimal etching condition for optimizing an etching amount deviation distribution when etching the first surface; and etching, under the optimal etching condition, the first surface of the substrate after being ground by supplying an etching liquid to the first surface from an etching liquid supply.

### Effect of the Invention

According to the exemplary embodiment, it is possible to appropriately control the surface shape of the substrate in the etching processing.

### BRIEF DESCRIPTION OF THE DRAWINGS

FIG. 1 is a plan view illustrating a schematic configuration of a wafer processing system.

FIG. 2 is a side view illustrating a schematic configuration of an etching device.

FIG. 3 is an explanatory diagram showing a state in which a nozzle is moving in a diametric direction.

FIG. 4 is a side view illustrating a schematic configuration of a grinding device.

FIG. 5 is an explanatory diagram illustrating a state in which a wafer surface is being ground in the grinding device.

FIG. 6 is a flowchart showing main processes of a wafer processing.

FIG. 7A to FIG. 7D are explanatory diagrams illustrating the main processes of the wafer processing.

FIG. 8 is an explanatory diagram illustrating an example of an etching amount deviation distribution.

FIG. 9 is a flowchart illustrating main processes of a method of optimizing the etching amount deviation distribution.

FIG. 10 is an explanatory diagram illustrating an example of a plurality of parts.

FIG. 11 is an explanatory diagram illustrating an example of parts used for superposition.

FIG. 12 is an explanatory diagram illustrating an example in which a plurality of optimized parts are superposed.

FIG. 13 is a flowchart illustrating main processes of a wafer processing.

FIG. 14 is a flowchart illustrating main processes of a wafer processing.

FIG. 15A to FIG. 15D are explanatory diagrams illustrating the main processes of the wafer processing.

FIG. 16 is a flowchart illustrating main processes of a wafer processing.

FIG. 17A to FIG. 17D are explanatory diagrams illustrating the main processes of the wafer processing.

FIG. 18 is a flowchart illustrating main processes of a wafer processing.

FIG. 19A to FIG. 19D are explanatory diagrams illustrating the main processes of the wafer processing.

FIG. 20 is an explanatory diagram illustrating an example of an etching amount deviation distribution.

FIG. 21 is an explanatory diagram illustrating an example shape of a first surface of a wafer after being subjected to grinding.

FIG. 22 is an explanatory diagram illustrating an example of a plurality of parts.

### DETAILED DESCRIPTION

In a manufacturing process for a semiconductor device, a cut surface of a disk-shaped silicon wafer (hereinafter, simply referred to as “wafer”) cut from a single crystalline silicon ingot with a wire saw or the like is flattened and smoothed to uniformize the thickness of the wafer. The flattening of the cut surface is performed by, for example, surface grinding or lapping. The smoothing of the cut surface is performed by, for example, spin etching of supplying an etching liquid from above the cut surface of the wafer while rotating the wafer.

It is described in the aforementioned Patent Document 1 that at least a surface of a wafer obtained by slicing a semiconductor ingot is flattened by the surface grinding or lapping and is then etched by the spin etching. In the spin etching process described in Patent Document 1, the spin etching is performed by supplying an etching liquid to the wafer while moving a discharge nozzle above an outer peripheral portion of the wafer at the beginning of the spin etching and then fixing the discharge nozzle above a central portion of the wafer whose outer peripheral portion has been etched.

However, the inventors of the present application have found out that when the etching liquid is supplied by fixing the position of the nozzle above the central portion of the wafer according to the method described in Patent Document 1, a surface shape of the wafer after being etched cannot be appropriately controlled, especially directly below the discharge of the etching liquid. Specifically, the inventors have observed that an etching amount at the central portion of the wafer directly below the discharge of the etching liquid is smaller than an etching amount at the outer peripheral portion around the central portion. The etching at the outer peripheral portion of the wafer progresses as the etching liquid supplied to the central portion flows to the outer peripheral portion of the wafer. Meanwhile, at the central portion directly below the discharge of the etching liquid, the supplied etching liquid is removed by a centrifugal force, which makes it difficult to form a flow (a flow velocity and a flow rate of the etching liquid) required to proceed with the etching on the surface of the wafer W.

In view of the foregoing, the present disclosure provides a technique capable of appropriately controlling a surface shape of a substrate in an etching processing. Hereinafter, a wafer processing system as a substrate processing system and a wafer processing method as a substrate processing method according to an exemplary embodiment will be described with reference to the accompanying drawings. In the present specification and the drawings, parts having substantially same functions and configurations will be assigned same reference numerals, and redundant description thereof will be omitted.

In a wafer processing system 1 according to the present exemplary embodiment, a wafer W as a substrate cut from an ingot is subjected to a processing of improving in-surface uniformity of the thickness thereof. Hereinafter, the cut surfaces of the wafer W will be respectively referred as a first surface Wa as one surface and a second surface Wb as the other surface. The first surface Wa is a surface opposite to the second surface Wb. The first surface Wa and the second surface Wb may sometimes be collectively referred to as a surface of the wafer W.

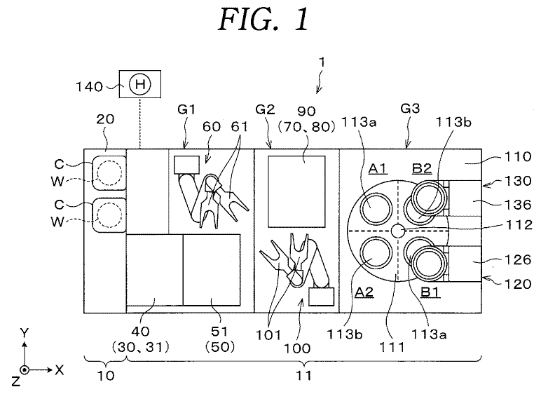

As depicted in FIG. 1, the wafer processing system 1 has a configuration in which a carry-in/out station 10 and a processing station 11 are connected as one body. In the carry-in/out station 10, a cassette C capable of accommodating therein a plurality of wafers W, for example, is carried to and from the outside. The processing station 11 is equipped with various types of processing apparatuses configured to perform required processes on the wafer W.

The carry-in/out station 10 is provided with a cassette placing table 20. In the shown example, the cassette placing table 20 is configured to place thereon a plurality of, for example, two cassettes C in a row in the Y-axis direction.

The processing station 11 is equipped with, for example, three processing blocks G1 to G3. The first processing block G1, the second processing block G2, and the third processing block G3 are arranged in this order from the negative X-axis side (carry-in/out station 10 side) to the positive X-axis side.

The first processing block G1 is equipped with inverting devices 30 and 31, a thickness measuring device 40, etching devices 50 and 51, and a wafer transfer device 60. The inverting device 30 and the etching device 50 are arranged in this order from the negative X-axis side to the positive X-axis side. The inverting devices 30 and 31 and the thickness measuring device 40 are stacked in this order from the bottom in a vertical direction, for example. The etching devices 50 and 51 are stacked in this order from the bottom in the vertical direction, for example. The wafer transfer device 60 is disposed on the positive Y-axis side of the etching devices 50 and 51. Here, the numbers and the layout of the inverting devices 30 and 31, the thickness measuring device 40, the etching devices 50 and 51, and the wafer transfer device 60 are not limited to the shown example.

The inverting devices 30 and 31 are configured to invert the first surface Wa and the second surface Wb of the wafer W in the vertical direction. The configuration of the inverting devices 30 and 31 is not particularly limited.

The thickness measuring device 40 includes, as an example, a measurement device (not shown) and a calculation device (not shown). The measurement device is equipped with a sensor configured to measure the thickness of the wafer W after being subjected to grinding or etching at multiple points. The calculation device acquires a thickness distribution of the wafer W from the measurement result (thickness of the wafer W) by the measurement device, and also calculates flatness (TTV: Total Thickness Variation) of the wafer W. Here, the calculation of the thickness distribution and the flatness of the wafer W may be performed by a control device 140 to be described later, instead of the calculation device. In other words, the calculation device (not shown) may be provided in the control device 140 to be described later. Additionally, the configuration of the thickness measuring device 40 is not limited to this example, and may be modified in various ways.

The etching devices 50 and 51 etch silicon (Si) of the first surface Wa after being ground or the second surface Wb after being ground in a processing device 110 to be described later.

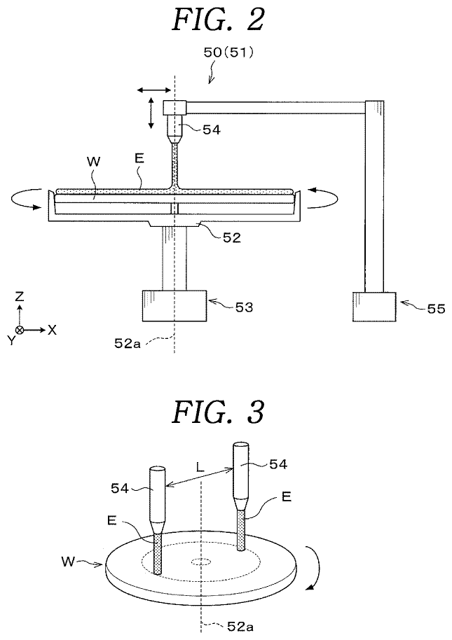

As shown in FIG. 2, each of the etching devices 50 and 51 has a wafer holder 52 as a substrate holder, a rotating mechanism 53, and a nozzle 54 as an etching liquid supply. The wafer holder 52 is configured to hold an edge portion of the wafer W at multiple points, for example, at three points in the present exemplary embodiment. The configuration of the wafer holder 52 is not limited to the shown example. By way of example, the wafer holder 52 may be equipped with a chuck configured to attract and hold the wafer W from below. The rotating mechanism 53 is configured to rotate the wafer W held by the wafer holder 52 about a vertical rotation center line 52a.

The nozzle 54 is configured to supply an etching liquid E to the first surface Wa or the second surface Wb of the wafer W held by the wafer holder 52. The nozzle 54 is connected to an etching liquid source (not shown) configured to supply the etching liquid E to the nozzle 54. The nozzle 54 is disposed above the wafer holder 52 and is configured to be movable in a horizontal direction and a vertical direction by a moving mechanism 55. As an example, the nozzle 54 is configured to reciprocate (scan) past the rotational center line 52a of the wafer holder 52, that is, to pass over the center of the wafer W, as shown in FIG. 3.

The etching liquid E contains at least hydrofluoric acid or nitric acid in order to properly etch the silicon of the wafer W that can be an etching target. In addition, the etching liquid E may contain phosphoric acid or sulfuric acid.

As illustrated in FIG. 1, the wafer transfer device 60 has, for example, two transfer arms 61 serving to hold and transfer the wafer W. Each transfer arm 61 is configured to be movable in a horizontal direction and a vertical direction and pivotable around a horizontal axis and a vertical axis. The wafer transfer device 60 is configured to transfer the wafer W to/from the cassette C of the cassette placing table 20, the inverting devices 30 and 31, the thickness measuring device 40, the etching devices 50 and 51, a buffer device 70 to be described later, a cleaning device 80 to be described later, and an inverting device 90 to be described later.

The second processing block G2 is equipped with the buffer device 70, the cleaning device 80, the inverting device 90, and the wafer transfer device 100. The buffer device 70, the cleaning device 80, and the inverting device 90 are stacked in this order from the bottom in the vertical direction, for example. The wafer transfer device 100 is disposed on the negative Y-axis side of the buffer device 70, the cleaning device 80, and the inverting device 90. Further, the numbers and the layout of the buffer device 70, the cleaning device 80, the inverting device 90, and the wafer transfer device 100 are not limited to the shown example.

The buffer device 70 is configured to temporarily hold the wafer W before being processed when it is transferred from the first processing block G1 to the second processing block G2. The configuration of the buffer device 70 is not particularly limited.

The cleaning device 80 is configured to clean the first surface Wa or the second surface Wb after being ground by the processing device 110 to be described later. For example, a brush may be brought into contact with the first surface Wa or the second surface Wb to clean the first surface Wa or the second surface Wb. Further, a pressurized cleaning liquid may be used to clean the first surface Wa or the second surface Wb. In addition, the cleaning device 80 may be configured to clean the first surface Wa and the second surface Wb at the same time when cleaning the wafer W.

Like the inverting devices 30 and 31, the inverting device 90 is configured to invert the first surface Wa and the second surface Wb of the wafer W in the vertical direction. The configuration of the inverting device 90 is not particularly limited.

The wafer transfer device 100 has, for example, two transfer arms 101 serving to hold and transfer the wafer W. Each transfer arm 101 is configured to be movable in the horizontal direction and the vertical direction and pivotable around a horizontal axis and a vertical axis. The wafer transfer device 100 is configured to transfer the wafer W to/from the etching devices 50 and 51, the buffer device 70, the cleaning device 80, the inverting device 90, and the processing device 110 to be described later.

The third processing block G3 is equipped with the processing device 110. Here, the number and the layout of the processing device 110 are not limited to the shown example.

The processing device 110 has a rotary table 111. The rotary table 111 is configured to be rotatable about a vertical rotation center line 112 by a rotating mechanism (not shown). On the rotary table 111, four chucks 113 are provided to attract and hold the wafer W. Among the four chucks 113, the two first chucks 113a are used for the grinding at a first processing position B1. These two first chucks 113a are positioned point-symmetrically with the rotation center line 112 therebetween. The rest two second chucks 113b are used for the grinding at a second processing position B2. These two second chucks 113b are also positioned point-symmetrically with the rotation center line 112 therebetween. That is, the first chucks 113a and the second chucks 113b are alternately arranged in a circumferential direction.

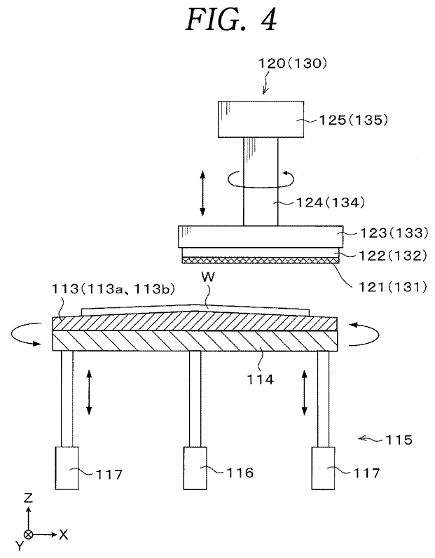

For example, a porous chuck is used as the chuck 113. A surface of the chuck 113, that is, a holding surface for the wafer W has a shape with a central portion protruding higher than an end portion when viewed from the side. Further, although the protrusion of this central portion of the chuck 113 is actually very minute, it is illustrated as being large for clarity of explanation in FIG. 4.

As depicted in FIG. 4, the chuck 113 is held on a chuck base 114. The chuck base 114 is provided with an inclination adjuster 115 configured to adjust the relative inclination between the chuck 113 and grinding whetstones 121 and 131 of grinding devices 120 and 130 to be described later. The inclination adjuster 115 has a fixed shaft 116 provided on a bottom surface of the chuck base 114 and a plurality of, for example, two elevating shafts 117. Each elevating shaft 117 is configured to be extensible and contractible and serves to move the chuck base 114 up and down. By elevating one end of an outer peripheral portion of the chuck base 114 in the vertical direction by the elevating shaft 117 with respect to the other end (the position corresponding to the fixed shaft 116) thereof by using this inclination adjuster 115, the chuck 113 and the chuck base 114 can be tilted. Thus, the relative inclination between the surface of the chuck 113 and surfaces of the grinding whetstones 121 and 131 of the grinding devices 120 and 130 at the processing positions B1 and B2 to be described later can be adjusted.

As shown in FIG. 1, the four chucks 113 can be moved to delivery positions A1 and A2 and the processing positions B1 and B2 as the rotary table 111 is rotated. Further, each of the four chucks 113 is configured to be rotatable around a vertical axis by a rotating mechanism (not shown).

The first delivery position A1 is a position on the negative X-axis and positive Y-axis side of the rotary table 111, where the wafer W is delivered onto the first chuck 113a when grinding the first surface Wa. The second delivery position A2 is a position on the negative X-axis and negative Y-axis side of the rotary table 111, where the wafer W is delivered onto the second chuck 113b when grinding the second surface Wb.

The first processing position B1 is a position on the positive X-axis and negative Y-axis side of the rotary table 111, and the first grinding device 120 is disposed thereat. As an example, the first grinding device 120 grinds the first surface Wa or the second surface Wb of the wafer W held by the first chuck 113a. The second processing position B2 is a position on the positive X-axis and positive Y-axis side of the rotary table 111, and the second grinding device 130 is disposed thereat. As an example, the second grinding device 130 grinds the second surface Wb or the first surface Wa of the wafer W held by the second chuck 113b.

Further, a thickness measuring device (not shown) configured to measure the thickness of the wafer W after being ground may be disposed at the delivery positions A1 and A2 or the processing positions B1 and B2.

As illustrated in FIG. 4, the first grinding device 120 includes a grinding wheel 122 having the grinding whetstone 121 of an annular shape on a bottom surface thereof; a mount 123 supporting the grinding wheel 122, a spindle 124 configured to rotate the grinding wheel 122 with the mount 123 therebetween, and a driver 125 having, for example, a motor (not shown) embedded therein. Further, the first grinding device 120 is configured to be movable in the vertical direction along a supporting column 126 shown in FIG. 1.

The second grinding device 130 has the same configuration as the first grinding device 120. That is, the second grinding device 130 has a grinding wheel 132 equipped with the grinding whetstone 131 of an annular shape, a mount 133, a spindle 134, a driver 135, and a supporting column 136.

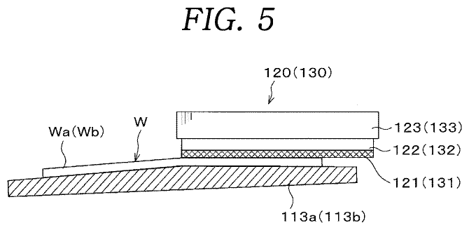

As shown in FIG. 5, when grinding the first surface Wa by using the first grinding device 120, the first chuck 113a is tilted so that the first surface Wa of the wafer W held on the first chuck 113a and the surface of the grinding whetstone 121 form a certain angle. For example, if the first surface Wa and the surface of the grinding whetstone 21 are parallel to each other, the first surface Wa may be ground flat. As another example, if the surface of the grinding whetstone 121 is tilted upwards radially outwards with respect to the first surface Wa, the first surface Wa may be ground into a V-shape in a cross sectional view. In addition, in the first grinding device 120, it is also possible to grind the first surface Wa into an A-shape, an M-shape, or a W-shape in a longitudinal cross sectional view. The annular grinding whetstone 121 comes into contact with an area of the wafer W ranging from the center to an outer end thereof in an arc line shape, and by rotating the first chuck 113a and the grinding wheel 122 in this state, the entire first surface Wa is ground. The same applies when grinding the second surface Wb by using the second grinding device 130.

The above-described wafer processing system 1 is provided with the control device 140 as shown in FIG. 1. The control device 140 is, by way of example, a computer equipped with a CPU, a memory, and the like, and has a program storage (not shown). The program storage stores therein a program for controlling a processing of the wafer W in the wafer processing system 1. Further, as mentioned above, the control device 140 may further include the calculation device (not shown) configured to acquire the thickness distribution of the wafer W from the measurement result (thickness of the wafer W) of the thickness measuring device 40 and, also, configured to calculate the flatness of the wafer W. Additionally, the program may have been recorded on a computer-readable recording medium H, and may be installed from the recording medium H into the control device 140. The recording medium H may be transitory or non-transitory.

Now, a wafer processing performed by using the wafer processing system 1 configured as described above will be explained. In the present exemplary embodiment, the wafer W, on which lapping is performed after being cut out from an ingot with a wire saw or the like, is subjected to a processing of improving in-surface uniformity of the thickness thereof.

First, the cassette C accommodating therein the plurality of wafers W is placed on the cassette placing table 20 of the carry-in/out station 10. In the cassette C, the wafer W is accommodated with the first surface Wa facing upwards and the second surface Wb facing downwards. Then, the wafer W in the cassette C is taken out by the wafer transfer device 60 and transferred to the buffer device 70.

Thereafter, the wafer W is transferred to the processing device 110 by the wafer transfer device 100, and delivered to the first chuck 113a at the first delivery position A1. Here, the second surface Wb of the wafer W is attracted to and held on the first chuck 113a.

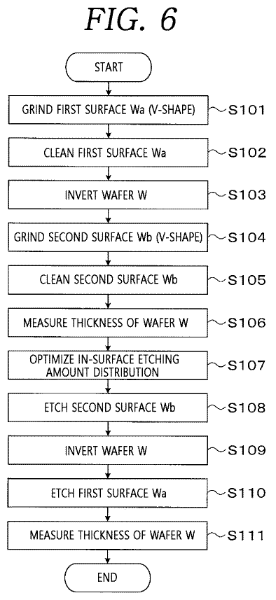

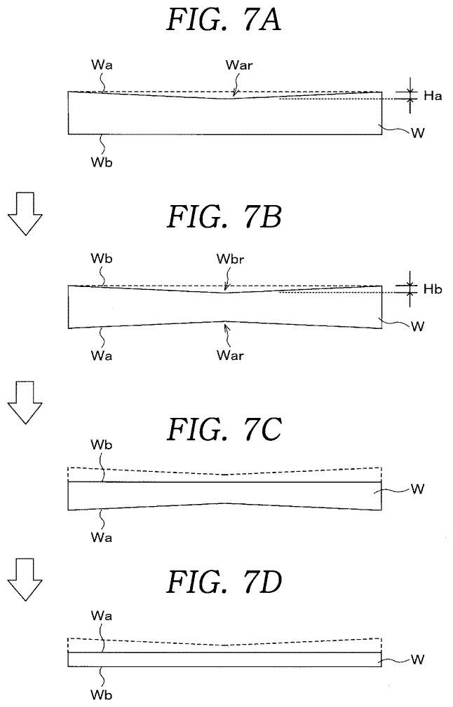

Next, the rotary table 111 is rotated to move the wafer W to the first processing position B1. Then, the first surface Wa of the wafer W is ground by the first grinding device 120 (process S101 in FIG. 6). In the process S101, the control device 140 controls the processing device 110 to grind the first surface Wa into a V-shape so that a recess portion War whose center is more depressed than an outer peripheral portion thereof is formed on the first surface Wa after being ground, as shown in FIG. 7A. Details of this V-shape will be described later.

Subsequently, the rotary table 111 is rotated to move the wafer W to the first delivery position A1. At the first delivery position A1, the first surface Wa of the wafer W after being ground may be cleaned by a cleaning device (not shown).

Next, the wafer W is transferred to the cleaning device 80 by the wafer transfer device 100. In the cleaning device 80, the first surface Wa and the second surface Wb of the wafer W are cleaned (process S102 in FIG. 6).

Then, the wafer W is transferred to the inverting device 90 by the wafer transfer device 100. In the inverting device 90, the first surface Wa and the second surface Wb of the wafer W are inverted in the vertical direction (process S103 in FIG. 6). That is, the wafer W is inverted with the first surface Wa facing downwards and the second surface Wb facing upwards.

Subsequently, the wafer W is transferred to the processing device 110 by the wafer transfer device 100, and delivered to the second chuck 113b at the second delivery position A2. Here, the first surface Wa of the wafer W is attracted to and held by the second chuck 113b.

Thereafter, the rotary table 111 is rotated to move the wafer W to the second processing position B2. Then, the second surface Wb of the wafer W is ground by the second grinding device 130 (process S104 in FIG. 6). In the process S104, the control device 140 controls the processing device 110 to grind the second surface Wb into a V-shape so that a recess portion Wbr whose center is more depressed than an outer peripheral portion thereof is formed on the second surface Wb after being ground, as shown in FIG. 7B. Details of this V-shape will be described later.

Next, the rotary table 111 is rotated to move the wafer W to the second delivery position A2. At the second delivery position A2, the second surface Wb of the wafer W after being ground may be cleaned by a cleaning device (not shown).

Thereafter, the wafer W is transferred to the cleaning device 80 by the wafer transfer device 100. In the cleaning device 80, the second surface Wb and the first surface Wa of the wafer W are cleaned (process S105 in FIG. 6).

Next, the wafer W is transferred to the thickness measuring device 40 by the wafer transfer device 60. The thickness measuring device 40 measures the thickness of the wafer W after being subjected to the grinding of the first surface Wa and the second surface Wb (process S106 in FIG. 6). Further, when the processing device 110 has a thickness measuring device, the thickness of the wafer W after being subjected to the grinding may be measured by the thickness measuring device of the processing device 110.

In the process S106, the thickness measuring device 40 measures the thickness of the wafer W at multiple points to obtain a thickness distribution of the wafer W after being subjected to the grinding, and also calculates flatness of the wafer W. The thickness distribution and the flatness of the wafer W thus calculated are outputted to, for example, the control device 140. (0:|7|

In the control device 140, optimal etching conditions for the subsequent etching processing of the first surface Wa and the second surface Wb are determined from the received thickness distribution and flatness of the wafer W, and an etching amount deviation distribution is optimized (process S107 in FIG. 6). A detailed method of optimizing the etching amount deviation distribution in the control device 140 will be described later. Here, an etching amount deviation represents a value (deviation) obtained by subtracting an average etching amount from an etching amount within a wafer surface. The average etching amount is an average value of etching amounts within the wafer surface.

Subsequently, the wafer W is transferred to the etching device 51 by the wafer transfer device 60. In the etching device 51, the second surface Wb of the wafer W is etched by the etching liquid E under the optimal etching conditions determined in the process S107 (process S108 in FIG. 6).

In the process S108, the wafer W is first held by the wafer holder 52 with the second surface Wb thereof facing upwards (towards the nozzle 54). Then, while rotating the wafer holder 52 (wafer W) around the vertical rotation center line 52a, the discharge of the etching liquid E from the nozzle 54 is begun to start the etching of the second surface Wb.

In the etching of the second surface Wb, while carrying on the discharge of the etching liquid E from the nozzle 54, the nozzle 54 is reciprocally moved (scanned) with the rotational center line 52a as a midpoint so that it passes over the rotational center of the wafer W, i.e., past the rotational center line 52a, as shown in FIG. 3. Here, a detailed method of determining etching conditions such as a rotation speed of the wafer W, a scan width of the nozzle 54, and a scan speed when reciprocating the nozzle 54 will be elaborated later.

Upon the completion of the etching of the second surface Wb under the optimal etching conditions, the supply of the etching liquid E from the nozzle 54 is stopped, and the second surface Wb of the wafer W is rinsed with pure water and dried by spinning. Thereafter, the rotation of the wafer holder 52 (wafer W) is stopped, and the etching of the wafer W is ended.

Here, as described above, the optimal etching conditions for the wafer W are determined in the process S107 based on the thickness distribution and the flatness of the wafer W after being ground. Specifically, the optimal etching conditions are determined based on differences between actual measurement values of the thickness distribution and flatness of the wafer W in the thickness measuring device 40 and thickness distribution and flatness in a target surface shape of the wafer W after being etched (hereinafter referred to as “target shape”). Then, in the process S108, by etching the second surface Wb under the optimal etching conditions, the etching amount deviation distribution is optimized, and the second surface Wb is processed into the target shape, for example, a flat shape in the present exemplary embodiment, as shown in FIG. 7C.

Next, the wafer W is transferred to the inverting device 31 by the wafer transfer device 60. In the inverting device 31, the first surface Wa and the second surface Wb of the wafer W are inverted in the vertical direction (process S109 in FIG. 6). That is, the wafer W is inverted with the first surface Wa facing upwards and the second surface Wb facing downwards.

Subsequently, the wafer W is transferred to the etching device 50 by the wafer transfer device 60. In the etching device 50, the first surface Wa of the wafer W is etched by the etching liquid E under the optimal etching conditions determined in the process S107 (process S110 in FIG. 6).

In the process S110, the first surface Wa is etched, like the second surface Wb in the process S108. That is, the wafer W is held by the wafer holder 52 with the first surface Wa thereof facing upwards. Then, while rotating the wafer holder 52 (wafer W), the discharge of the etching liquid E from the nozzle 54 is begun to start the etching of the first surface Wa. Thereafter, while carrying on the discharge of the etching liquid E from the nozzle 54, the nozzle 54 is reciprocally moved (scanned) with the rotation center line 52a as a midpoint as shown in FIG. 3 to etch the first surface Wa.

In this process S110, as in the process S108, by etching the first surface Wa under the optimal etching conditions, the etching amount deviation distribution is optimized, and the first surface Wa is processed into a target shape, for example, a flat shape in the present exemplary embodiment, as illustrated in FIG. 7D. That is, the target shape of the wafer W is flat, and the thickness distribution of the wafer W becomes uniform.

Next, the wafer W is transferred to the thickness measuring device 40 by the wafer transfer device 60. In the thickness measuring device 40, the thickness of the wafer W after being subjected to the etching of both the first surface Wa and the second surface Wb is measured (process S111 in FIG. 6).

In the process S111, the thickness measuring device 40 measures at multiple points the thickness of the wafer W after being subjected to the etching of both surfaces to acquire a thickness distribution of the wafer W after being etched, and also calculates flatness of the wafer W. The thickness distribution and the flatness of the wafer W thus calculated are outputted to, for example, the control device 140, and are used for another wafer W to be processed next in the wafer processing system 1.

Thereafter, the wafer W after being subjected to all the required processes is transferred to the cassette C on the cassette placing table 20 by the wafer transfer device 60. In this way, the series of processes of the wafer processing in the wafer processing system 1 are ended. Additionally, at the outside of the wafer processing system 1, polishing may be performed on the wafer W after being subjected to the required processing in the wafer processing system 1.

Now, the detailed methods of grinding the first surface Wa (process S101), grinding the second surface Wb (process S104), and optimizing the etching amount deviation distributions of the first surface Wa and the second surface Wb (process S107) will be described.

As described above, in the process S108, while rotating the wafer W and reciprocating (scanning) the nozzle 54 in the diametric direction past the center of the wafer W, the etching liquid E is supplied from the nozzle 54 onto the first surface Wa of the wafer W to etch the first surface Wa. Hereinafter, such etching may be referred to as “scan etching.” In addition, in the process S110, the second surface Wb of the wafer W is scan-etched.

Here, in order to control a surface shape of the wafer W after being etched, it is required to optimize an etching amount deviation distribution (etching profile) in the diametric direction of the wafer W. Then, in the process S107, the etching amount deviation distribution is optimized by adjusting etching conditions (etching recipe) such as a rotation speed (rotation number) of the wafer W, a scan speed in the reciprocating movement of the nozzle 54, and a scan width.

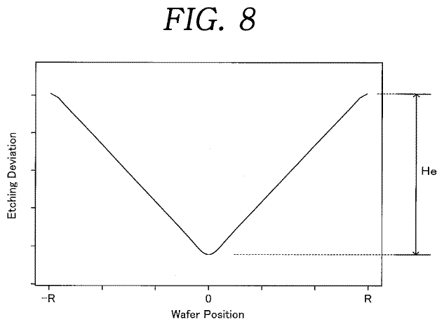

Meanwhile, the etching amount deviation distribution of the scan etching tends to become a V-shape recessed downwards due to the nature of the process, with a less etching amount deviation near the center (0 (zero) on a horizontal axis) of the wafer W as shown in FIG. 8. The horizontal axis of FIG. 8 represents a position in the diametric direction from the center (0 (zero) on the horizontal axis) to an outer edge (±R on the horizontal axis) of the wafer, and a vertical axis represents an etching deviation (a difference from an average etching amount). In other words, the surface of the wafer after being etched is likely to become an A-shape that protrudes upwards. Therefore, if it is attempted to flatten the surface of the wafer by optimizing the etching amount deviation distribution in the process S107 when the surface shape of the wafer after being ground is not a V-shape, a required etching amount deviation may not be generated by the optimization calculation, and there is a risk that the surface of the wafer after being etched may not be flat. That is, if the surface shape of the wafer after being ground is not a V-shape, there may be a big error in the optimization of the etching amount deviation distribution in the process S107. Therefore, it is desirable to form the surface shape of the wafer after being ground into a V-shape.

In addition, in the etching amount deviation distribution of the scan etching, there is an upper limit in a height He of the V-shape due to the nature of the process. This limit height He of the etching amount deviation distribution is a difference between the maximum and minimum values of the etching amount deviation distribution, and is an upper limit that is controllable in the etching. Therefore, for example, if it is attempted to flatten the surface of the wafer by optimizing the etching amount deviation distribution in the process S107 when the height of the V-shape in the surface of the wafer after being ground is large, a required etching amount deviation may not be generated by the optimization calculation, and there is a concern that the surface of the wafer after being etched may not be flat. That is, when the height of the V-shape after the grinding is large, there may be a big error in the optimization of the etching amount deviation distribution in the process S107. Therefore, it is desirable that the height of the V-shape in the surface of the wafer after being ground is equal to or less than the limit height He of the etching amount deviation distribution.

In consideration of the foregoing, in the process S101, the control device 140 controls the processing device 110 to grind the first surface Wa into the V-shape so that the recess portion War whose center is more depressed than the outer peripheral portion thereof is formed on the first surface Wa after being ground, as shown in FIG. 7A. A height Ha of the recess portion War is set to be equal to or less than the limit height He of the etching amount deviation distribution. This limit height He is determined based on the etching conditions such as, but not limited to, a supply time of the etching liquid E, a rotation speed of the wafer W, a scan speed in the reciprocating movement of the nozzle 54, and a scan width. The limit height He is, for example, 1.0 μm or less.

Likewise, in the process S104, the control device 140 controls the processing device 110 to grind the second surface Wb into the V-shape so that the recess portion War whose center is more depressed than the outer peripheral portion thereof is formed on the second surface Wb after being ground, as shown in FIG. 7B. A height Hb of the recess portion Wbr is set to be equal to or less than the limit height He of the etching amount deviation distribution.

In this way, by grinding the first surface Wa and the second surface Wb into the shape controllable by the etching in the processes S101 and S104, respectively, the etching amount deviation distributions of the first surface Wa and the second surface Wb in the processes S108 and S110 can be appropriately optimized.

In the process S107, optimal etching conditions for the subsequent etching processing of the first surface Wa and the second surface Wb are determined from the thickness distribution and the flatness of the wafer W after being subjected to the grinding of both surfaces, which are obtained in the process S106, to optimize the etching amount deviation distributions.

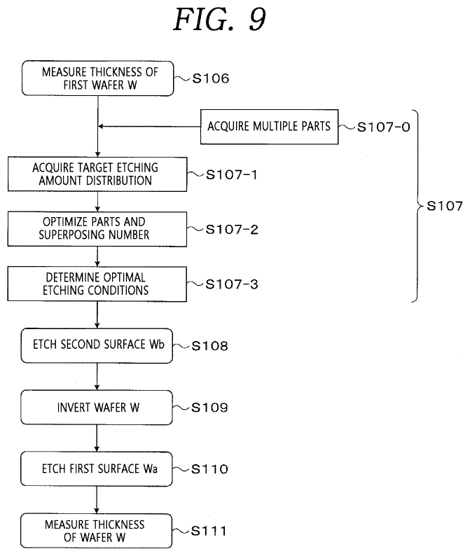

In determining the optimal etching conditions (optimizing the etching amount deviation distribution), a plurality of parts to be used in an optimization process to be described later are acquired (process S107-0 in FIG. 9) prior to performing the processing on the wafer W in the wafer processing system 1. Here, each part is an etching amount deviation distribution of the wafer W for a certain etching condition.

In the process S107-0, etching is performed on dummy wafers under a plurality of different etching conditions, for example. Specifically, the etching of the dummy wafers is performed while changing, for example, rotation speeds of the dummy wafers during the etching, a scan speed of the nozzle 54, a scan width (see scan width L in FIG. 3) of the nozzle 54, or the like. At this time, an etching time for each dummy wafer is set to be the same. Etching of each dummy wafer is performed by supplying the etching liquid E from the nozzle 54 to the dummy wafer while rotating the dummy wafer and reciprocating the nozzle 54, the same as in the etching in the processes S108 and S110. In the following description, a reciprocating movement of the nozzle 54 between two opposite ends of the dummy wafer is referred to as one loop.

The etching of the dummy wafer under each etching condition is performed for a predetermined required time (in a required number of loops). Then, an etching amount deviation distribution of the dummy wafer is acquired, and the acquired etching amount deviation distribution is outputted to the control device 140. The control device 140 compresses the received etching amount deviation distribution under each etching condition into an etching amount deviation distribution in unit time (unit number of loops), and stores the compressed etching amount deviation distribution as the aforementioned part.

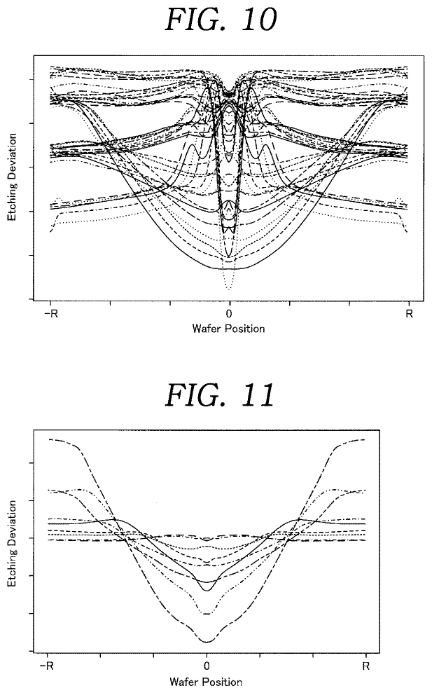

FIG. 10 shows an example of the plurality of parts. A horizontal axis of FIG. 10 represents a position in the diametric direction from the center (0 (zero) on the horizontal axis) to an outer edge (±R on the horizontal axis) of the wafer, and a vertical axis represents an etching deviation. In the example shown in FIG. 10, a total of 36 types of parts are stored in the control device 140. In other words, FIG. 10 shows an example case where the etching amount deviation distribution is obtained under a total of 36 different etching conditions.

In addition, the unit time (unit number of loops) can be set arbitrarily according to the purpose involved. In order to appropriately obtain a target etching amount deviation distribution in superposition of the parts to be described later, it is desirable that the unit time (unit number of loops) is small. As an example, the unit time of the parts stored in the control device 140 may be a time period for 1 loop (1 round trip of the scan width L shown in FIG. 3), desirably, a time period for 0.5 loop (half-round trip of the scan width L shown in FIG. 3).

In addition, although the above description has been given for the case where the part is acquired by etching the dummy wafer, the etching target when acquiring the part is not limited to the dummy wafer. As a specific example, an etching result of the wafer W actually processed in the wafer processing system 1 may be stored as the part.

In the wafer processing in the wafer processing system 1 according to the present disclosure, optimal etching conditions are determined by using the plurality of parts (FIG. 10) acquired in this way.

First, based on a thickness distribution in the target shape of the wafer W after being etched and a thickness distribution in the surface shape of the wafer W after being ground (hereinafter, referred to as “actual shape”) acquired in the process S106, target etching amount deviation distributions in the etching processing in the processes S108 and S110 are acquired (process S107-1 in FIG. 9). In the present exemplary embodiment, the target shape of each of the first surface Wa and the second surface Wb is a flat shape. As an example, each of the target etching amount deviation distributions of the first surface Wa and the second surface Wb can be acquired by dividing in half a value obtained by subtracting, from a difference between the thickness distribution of the target shape of the wafer W and the thickness distribution of the actual shape of the wafer W, an average value of the difference. Specifically, each of the target etching amount deviation distributions of the first surface Wa and the second side Wb is V-shaped, as shown in FIG. 8.

Next, in order to achieve the target etching amount deviation distribution acquired in the process S107-1 by superposing multiple parts, the parts to be used in the superposition and the superposing number of the parts are optimized by using an optimization method (process S107-2 in FIG. 9).

In the process S107-2, the parts and the superposing number of the parts are optimized by applying a control of the etching amount deviation distribution to a knapsack problem, for example. By way of example, the etching amount deviation distribution is a knapsack of the knapsack problem, and the parts are items of the knapsack problem. Then, the parts and the superposing number of the parts are optimized so that a difference between a superposed etching amount deviation distribution and a target etching amount deviation distribution is minimized.

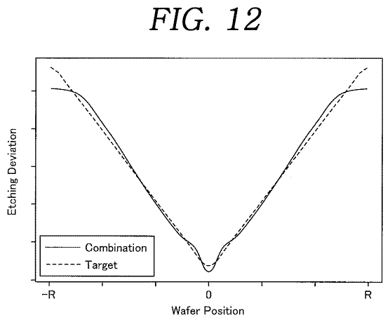

As an example of this optimization method, a genetic algorithm or a dynamic programming method may be used. By executing optimization calculation, one or more parts to be used for the superposition are selected as shown in FIG. 111 from the plurality of parts shown in FIG. 10, and the selected parts are superposed as shown in FIG. 12. The superposed etching amount deviation distribution (solid line in FIG. 12) approximates the target etching amount deviation distribution (dashed line in FIG. 12).

Also, in this optimization calculation, the parts and the superposing number of the parts are optimized so that the supply time of the etching liquid E from the nozzle 54 to the wafer W in the etching processing is minimized. In this way, in the present exemplary embodiment, so-called multi-purpose optimization is performed in which both the etching amount deviation distribution, that is, etching precision, and the supply time of the etching liquid E are optimized. Specifically, they are optimized by using the following Expression 1. Here, the etching precision refers to precision of the etching amount deviation distribution within the surface of the wafer.

$$\begin{matrix}[ Expression 1 ] & \\ Min \{ α \cdot TTV + ( 1 - α ) \cdot {RMSE}_{centerized} \} s . t . {L}_{lower} \leq {t}_{dispense} \leq {L}_{upper} & ( 1 )\end{matrix}$$

Here, a denotes a coefficient ranging from 0 (zero) to 1; TTV, flatness of the actual shape; RMSE_{centerized}, non-uniformity of the thickness distribution of the wafer; t_{dispense}, the supply time of the etching liquid E; L_{lower}, lower limit set arbitrarily; and Lᵤₚₚₑᵣ, an upper limit set arbitrarily.

In the process S107-2, a loss function of the etching amount deviation distribution (etching precision) is calculated as a weighted linear sum of the flatness of the actual shape and the non-uniformity of the thickness distribution of the actual shape, as shown by Expression (1). For example, when the coefficient α is 0.5 in Expression (1), the flatness (TTV) and the non-uniformity (RMSE) of the thickness distribution have the same weight. Meanwhile, when the coefficient α is, e.g., 1, it becomes an algorithm that emphasizes the flatness, whereas when the coefficient α is 0 (zero), it becomes an algorithm that emphasizes the uniformity of the thickness distribution.

In the process S107-2, to optimize the superposing number of the parts, the superposing number may be optimized in the unit of 0.5 loop. In this case, it becomes possible to start the supply of the etching liquid E from the center of the wafer W and end it at the center as well, for example.

Once the parts and the superposing number of the parts are optimized, etching conditions corresponding to the parts optimized in the process S107-2 are integrated to determine the optimal etching conditions (process S107-3 in FIG. 9). Specifically, the optimal etching conditions are determined by integrating selected multiple etching conditions so that the multiple etching conditions are performed with the optimized superposing number. The optimal etching conditions include, by way of non-limiting example, a rotation speed of the wafer W during the etching, a scan speed or scan width of the nozzle 54, and so forth.

As described above, the optimal etching conditions for the first surface Wa and the second surface Wb are respectively determined, and the etching amount deviation distributions of the first surface Wa and the second surface Wb are optimized.

According to the above-described exemplary embodiment, in the processes S101 and S104, the first surface Wa and the second surface Wb are ground into the V-shape, and the heights Ha and Hb of the recess portions War and Wbr are set to be equal to or lower than the limit height He of the etching amount deviation distributions. In this way, by grinding the first surface Wa and the second surface Wb into a shape controllable by the etching in the processes S101 and S104, the precision of the optimization of the etching amount deviation distributions of the first surface Wa and the second surface Wb in the processes S108 and S110 can be improved.

In addition, in the process S107, since optimal etching conditions for the subsequent etching processing of the first surface Wa and the second surface Wb are determined from the thickness distribution and the flatness of the wafer W after being subjected to the grinding of both surfaces in the process S106, etching amount deviation distributions can be optimized.

Besides, in the process S107, since the optimal etching conditions are determined by optimizing the parts to be superposed and the superposing number of the parts by using the optimization method, the first surface Wa and the second surface Wb can be etched under these optimal etching conditions in the processes S108 and S110 afterwards. Accordingly, the etching amount deviation distribution in the etching processing can be made close to the target etching amount deviation distribution, and, as a result, the surface shape of the wafer W after being etched can be made into the target shape. In other words, the optimal etching conditions can be determined from random etching conditions, so that the surface shape of the wafer W after being etched can be appropriately controlled.

Furthermore, since the processes S101 to S111 are performed for each wafer W, the surface shape of the wafer W after being etched can be controlled wafer by wafer.

In the above-described exemplary embodiment, in the process S107, the optimal etching conditions for the subsequent etching processing of the first surface Wa and the second surface Wb are determined from the thickness distribution and the flatness of the wafer W after being subjected to the grinding of both surfaces, which are acquired in the process S106, to optimize the etching amount deviation distributions. However, the thickness distribution and the flatness of the wafer W may be acquired each time when optimizing the etching amount deviation distributions of the first surface Wa and the second surface Wb, respectively.

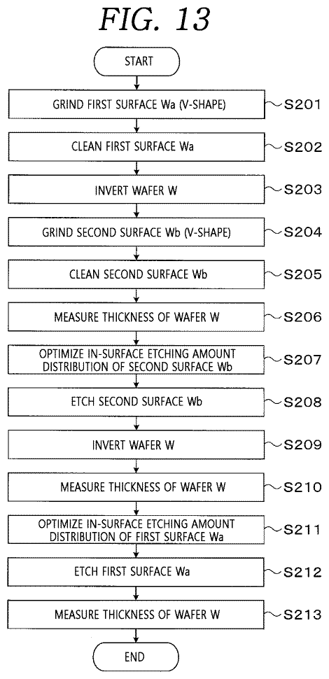

Specifically, as illustrated in FIG. 13, processes S201 to S206 are performed to carry out double-sided grinding, double-sided cleaning, and thickness measurement. These processes S201 to S206 are the same as the processes S101 to S106 of the above-described exemplary embodiment. In the processes S201 and S204, the first surface Wa and the second surface Wb are ground into a V-shape, as shown in FIG. 7A and FIG. 7B, respectively.

In a process S207, optimal etching conditions for the second surface Wb are determined from thickness distribution and flatness of the wafer W acquired in the process S206, and an etching amount deviation distribution of the second surface Wb is optimized. Then, in a process S208, the second surface Wb is etched under the determined optimal etching conditions, as shown in FIG. 7C. These processes S207 and S208 are the same as the processes S107 and S108 of the above-described exemplary embodiment. Thereafter, in the process S209, the first surface Wa and the second surface Wb are inverted upside down. This process 209 is the same as the process S109 of the above-described exemplary embodiment.

In a process S210, the thickness of the wafer W is measured at multiple points to obtain a thickness distribution of the wafer W after being ground, and flatness of the wafer W is also calculated. Then, in a process S211, optimal etching conditions for the first surface Wa are determined from the thickness distribution and the flatness of the wafer W, and an etching amount deviation distribution of the first surface Wa is optimized. Then, in a process S212, the first surface Wa is etched under the determined optimal etching conditions. These processes S210 to S212 are the same as the processes S106, S107 and S110 of the above-described exemplary embodiment.

In a process S213, the thickness of the wafer W is measured at multiple points to obtain a thickness distribution of the wafer W after being ground, and flatness of the wafer W is also calculated. This process S213 is the same as the process S111 of the above-described exemplary embodiment. In this case, the first surface Wa and the second surface Wb can be precisely etched.

In the exemplary embodiment described above, after both surfaces of the wafer W are ground into the V-shape, the etching amount deviation distributions of both surfaces are optimized. However, the grinding of the wafer W and the optimization of the etching amount deviation distribution may be performed in different patterns from those described above.

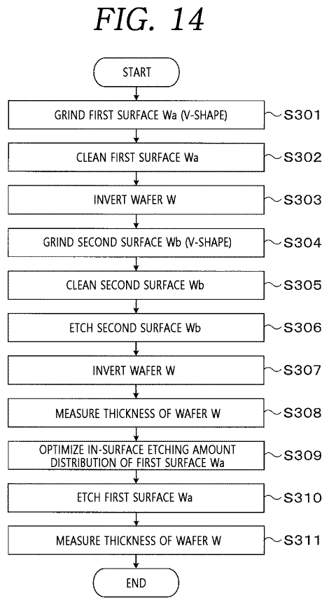

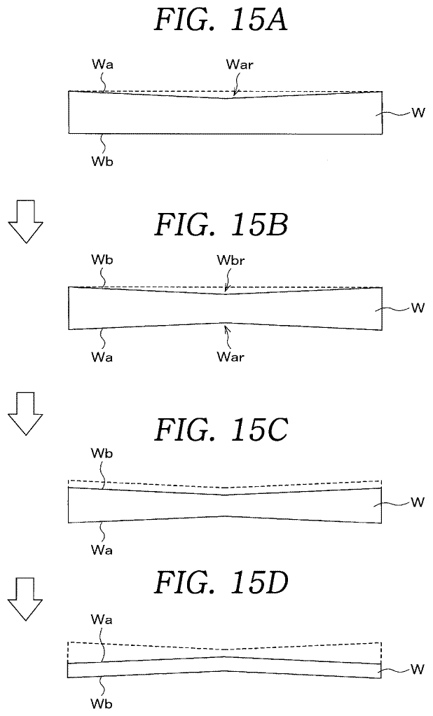

As shown in FIG. 14 to FIG. 15D, after grinding both surfaces of the wafer W into a V-shape, an etching amount deviation distribution of only one surface may be optimized.

Processes S301 to S305 are performed to carry out double-side grinding and double-side cleaning. These processes S301 to S305 are the same as the processes S101 to S105 of the above-described exemplary embodiment. In the process S301, the first surface Wa is ground into a V-shape such that the recess portion War whose center is more depressed than its outer peripheral portion is formed on the first surface Wa after being ground, as illustrated in FIG. 15A. In the process S304, the second surface Wb is ground into a V-shape such that the recess portion Wbr whose center is more depressed than its outer peripheral portion is formed on the second surface Wb after being ground, as illustrated in FIG. 15B.

In a process S306, the second surface Wb is etched as shown in FIG. 15C. At this time, an etching amount deviation of the second surface Wb is uniform within the surface thereof, that is, an etching amount deviation distribution is uniform. Thereafter, in a process S307, the first surface Wa and the second surface Wb are inverted upside down. This process S307 is the same as the process S109 of the above-described exemplary embodiment.

In a process S308, the thickness of the wafer W is measured at multiple points to obtain a thickness distribution of the wafer W after being ground, and flatness of the wafer W is also calculated. Then, in a process S309, optimal etching conditions in an etching processing for the first surface Wa are determined from the thickness distribution and the flatness of the wafer W acquired in the process S308, and an etching amount deviation distribution is optimized. These processes S308 to S309 are the same as the processes S106 and S107 of the above-described exemplary embodiment.

In a process S310, the first surface Wa is etched under the optimal etching conditions determined in the process S309, as shown in FIG. 15D. That is, in the present exemplary embodiment, the thickness distribution of the wafer W after being etched becomes uniform. This process S310 is the same as the process S110 of the above-described exemplary embodiment.

Thereafter, in a process S311, the thickness of the wafer W is measured at multiple points to obtain a thickness distribution of the wafer W after being ground, and flatness of the wafer W is also calculated. This process S311 is the same as the process S111 of the above-described exemplary embodiment.

Further, in the present exemplary embodiment, when the processes S301 to S311 are performed consecutively on a plurality of wafers W, the etching amount deviation of the second surface Wb is uniform within the surface of each wafer W in the process S306. In other words, the second surface Wb is etched under the same etching conditions for the plurality of wafers W.

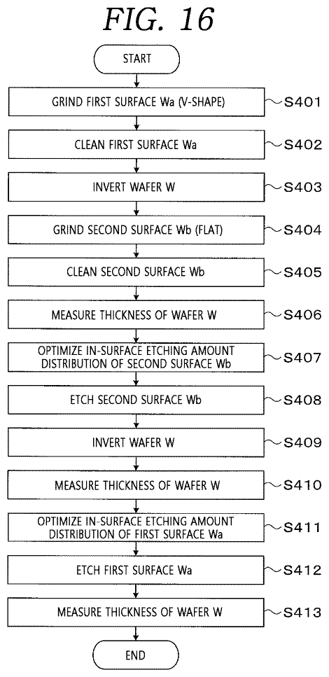

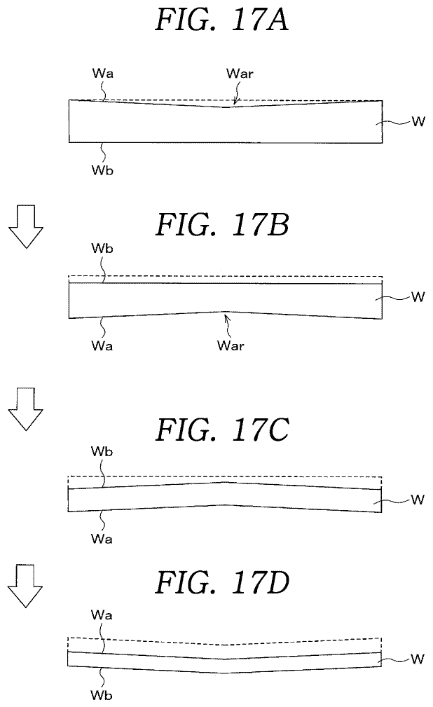

As shown in FIG. 16 to FIG. 17D, after one surface of the wafer W is ground into a V-shape and the other surface is ground flat, etching amount deviation distributions of the two surfaces may be optimized.

Processes S401 to S406 are performed to carry out double-sided grinding, double-sided cleaning, and thickness measurement. These processes S401 to S406 are the same as the processes S101 to S106 of the above-described exemplary embodiment except that the second surface Wb is ground flat. In the process S401, the first surface Wa is ground into a V-shape so that the recess portion War whose center is more depressed than its outer peripheral portion is formed on the first surface Wa after being ground, as shown in FIG. 17A. Then, in a process S304, the second surface Wb is ground flat, as shown in FIG. 17B.

In a process S407, optimal etching conditions for an etching processing of the second surface Wb are determined from thickness distribution and flatness of the wafer W after being subjected to the double-sided grinding, which is acquired in the process S406, to optimize an etching amount deviation distribution. This process S407 is the same as the process S107 of the above-described exemplary embodiment.

In a process S408, the second surface Wb is etched under the optimal etching conditions determined in the process S407, as illustrated in FIG. 17C. Thereafter, in a process S409, the first surface Wa and the second surface Wb are inverted upside down. These processes S408 and S409 are the same as the processes S108 and S109 of the above-described exemplary embodiment.

In a process S410, the thickness of the wafer W is measured at multiple points to obtain a thickness distribution of the wafer W after being ground, and flatness of the wafer W is also calculated. In a process S411, optimal etching conditions for an etching processing of the first surface Wa are determined from the thickness distribution and the flatness of the wafer W obtained in the process S410, and an etching amount deviation distribution is optimized. These processes S410 and S411 are the same as the processes S106 and S107 of the above-described exemplary embodiment.

In a process S412, the first surface Wa is etched under the optimal etching conditions determined in the process S411, as illustrated in FIG. 17D. That is, in the present exemplary embodiment, the thickness distribution of the wafer W after being etched becomes uniform. This process S412 is identical to the process S110 of the above-described exemplary embodiment.

Subsequently, in a process S413, the thickness of the wafer W is measured at multiple points to obtain a thickness distribution of the wafer W after being ground, and flatness of the wafer W is also calculated. This process S413 is the same as the process S111 of the above-described exemplary embodiment.

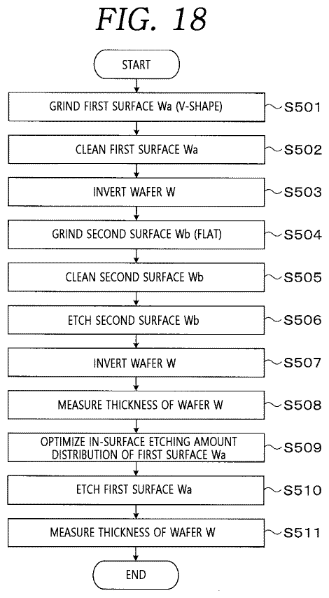

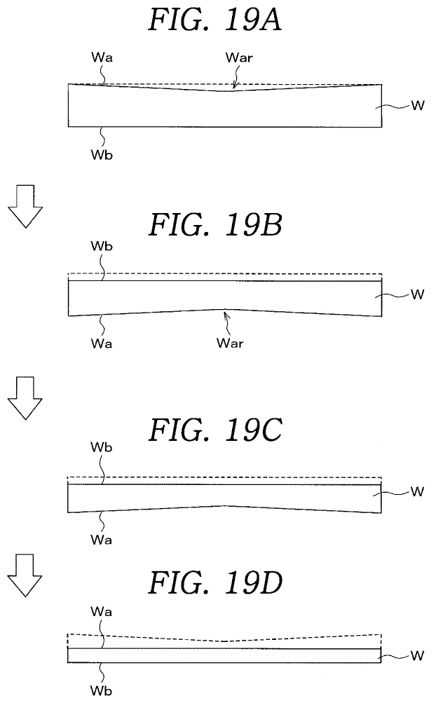

As shown in FIG. 18 to FIG. 19D, after one surface of the wafer W is ground into a V-shape and the other surface is ground flat, an etching amount deviation distribution of only one of the two surfaces may be optimized.

Processes S501 to S505 are performed to carry out double-sided grinding and double-sided cleaning. These processes S501 to S505 are the same as the processes S101 to S105 of the above-described exemplary embodiment except that the second surface Wb is ground flat. In the process S501, the first surface Wa is ground into a V-shape such that the recess portion War whose center is more depressed than the outer peripheral thereof is formed on the first surface Wa after being ground, as illustrated in FIG. 19A. In the process S504, the second surface Wb is ground flat, as shown in FIG. 19B.

In a process S506, the second surface Wb is etched as depicted in FIG. 19C. At this time, an etching amount deviation of the second surface Wb is uniform within the surface, i.e., an etching amount deviation distribution is uniform. Thereafter, in a process S307, the first surface Wa and the second surface Wb are inverted upside down. This process S507 is the same as the process S109 of the above-described exemplary embodiment.

In a process S508, the thickness of the wafer W is measured at multiple points to obtain a thickness distribution of the wafer W after being ground, and flatness of the wafer W is also calculated. In a process S509, optimal etching conditions for the etching processing of the first surface Wa are determined from the thickness distribution and the flatness of the wafer W obtained in the process S508, and an etching amount deviation distribution is optimized. These processes S508 and S509 are the same as the processes S106 and S107 of the above-described exemplary embodiment.

In a process S510, the first surface Wa is etched under the optimal etching conditions determined in the process S509, as illustrated in FIG. 19D. That is, in this exemplary embodiment, the thickness distribution of the wafer W after being etched becomes uniform. This process S310 is the same as the process S110 of the above-described exemplary embodiment.

Thereafter, in a process S511, the thickness of the wafer W is measured at multiple points to acquire a thickness distribution of the wafer W after being ground, and flatness of the wafer W is also calculated. This process S511 is the same as the process S111 of the above-described exemplary embodiment.

In addition, in this embodiment, when the processes S501 to S511 are performed continuously for multiple wafers W, the etching amount deviation of the second surface Wb is uniform within the surface in the process S506. In other words, the second surface Wb is etched for multiple wafers W under the same etching conditions.

Which one of the patterns shown in FIG. 7A to FIG. 7D, FIG. 15A to FIG. 15D, FIG. 17A to FIG. 17D, and FIG. 19A to FIG. 19D will be adopted to perform grinding and etching may be selected based on a target shape after the etching, processing times for the grinding and the etching, consumption of the etching liquid E, and so forth.

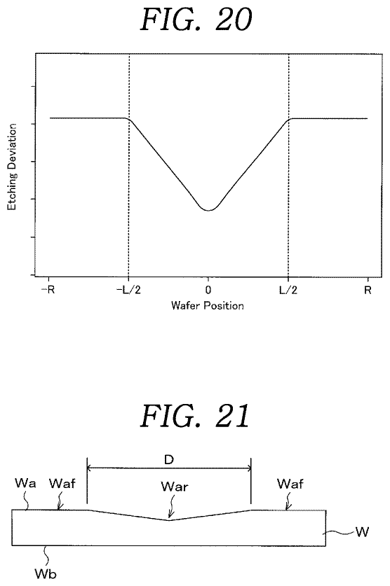

Here, in the grinding in the processes S101 and S104 as described above, it is possible to control the surface shape of the wafer W up to its outermost periphery. Meanwhile, in the scan etching in the processes S108 and S110, in order to suppress a splash of the etching liquid E, the etching amount deviation distribution can be controlled only in an area inside the scan width L as shown in FIG. 20, and in an area outside the scan width L, the etching amount deviation distribution becomes flat and cannot be controlled in some cases. In such cases, there may be a big error in the optimization of the etching amount deviation distribution in the process S107.

To solve the problem, in the process S101, as illustrated in FIG. 21, the recess portion War whose center is more depressed than the outer peripheral portion thereof and a flat portion Waf provided around the recess portion War may be formed on the first surface Wa after being ground. The recess portion War has a V-shape in a cross sectional view, and is formed to have a circular shape having the same center as the first surface Wa when viewed from the top. A diameter D of the recess portion War is equal to or less than the scan width L. The flat portion Waf is formed to have an annular shape having the same center as the first surface Wa when viewed from the top. In addition, a boundary point between the recess portion War and the flat portion Waf is determined according to, for example, an inflection point of the grinding in the processing device 110.

In addition, in the process S104 as well, the recess portion Wbr whose center is more depressed than the outer peripheral thereof and a flat portion Wbf provided around the recess portion Wbr may be formed on the second surface Wb after being ground.

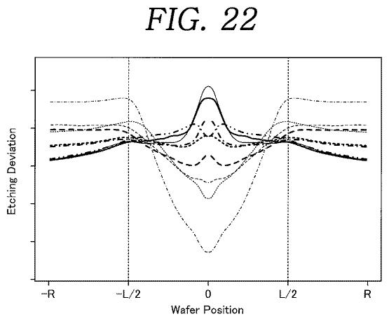

In the process S107, when optimizing the etching amount deviation distribution of the first surface Wa, a plurality of a plurality of parts as shown in FIG. 22 is acquired in the process S107-0. Then, the acquisition of the target etching amount deviation distributions in the process S107-1, the optimization of the parts and the superposing number of the parts in the process S107-2, and the determination of the optimal etching conditions in the process S107-3 are performed in the same manner as in the above-described exemplary embodiment.

According to the present exemplary embodiment, by grinding the first surface Wa and the second surface Wb into shapes controllable by the etching in the processes S101 and S104, the precision in the optimization of the etching amount deviation distributions of the first surface Wa and the second surface Wb in the processes S108 and S110 can be further improved.

In addition, in the case where the recess portion War and the flat portion Waf are formed on the first surface Wa after being ground in the process S101, the processing device 110 may have two types of grinding devices (grinding shafts). By way of example, in the present exemplary embodiment, after the entire first surface Wa is formed flat in the first grinding device 120, the vicinity of the center of the first surface Wa is ground in the second grinding device 130 to form the recess portion War.

In the above-described exemplary embodiment, although the etching processing of the first surface Wa and the second surface Wb of the wafer W is controlled based on the etching amount deviation distribution (distribution of the values obtained by subtracting the average etching amount from the etching amounts within the surface of the wafer), it may be controlled based on a distribution of the etching amounts (absolute values). For example, if the etching amount deviation distribution is optimized, the shape (profile) of the wafer W after being etched can be precisely controlled, and if the etching amount is optimized, the shape of the wafer W after being etched can be precisely controlled, and, also, the thickness of the wafer W can be precisely controlled. Furthermore, the shape of the wafer W can be controlled more precisely by controlling it based on the etching amount deviation distribution than by controlling it based on the etching amount. Therefore, when the shape of the wafer W needs to be controlled more precisely, it is desirable to perform the control based on the etching amount deviation distribution. When it is required to control the thickness of the wafer W precisely according to the shape of the wafer W, it is desirable to perform the control based on the etching amount. Additionally, in the etching processing of the first surface Wa and the second surface Wb of the wafer W, the control based on the etching amount deviation distribution and the control based on the etching amount may be combined.

Moreover, although the above exemplary embodiment has been described for the example where the various processes are performed on both surfaces (the first surface Wa and the second surface Wb) of the wafer W lapped after being cut out from the ingot with the wire saw or the like, the various processes may be performed only on one surface of the wafer W.

In addition, although the above exemplary embodiment has been described for the example where the various processes are performed on the wafer W lapped after being cut out from the ingot with the wire saw or the like, the technique of the present disclosure may also be applicable to, for example, a post-processing in a semiconductor device manufacturing process. As a specific example, in a combined wafer formed by bonding a first wafer and a second wafer, the technique of the present disclosure can be applied to a case of grinding the first wafer and then etching the surface of the first wafer after being ground.

It should be noted that the above-described exemplary embodiment is illustrative in all aspects and is not anyway limiting. The above-described exemplary embodiment may be omitted, replaced and modified in various ways without departing from the scope and the spirit of claims.

### EXPLANATION OF CODES

1: Wafer processing system
40: Thickness measuring device
50, 51: Etching device
54: Nozzle
110: Processing device
140: Control device
W: Wafer
War: Recess portion

The invention claimed is:

1. A substrate processing method of processing a substrate, comprising:
grinding a first surface of the substrate to form, on the first surface, a recess portion whose center is more depressed than an outer peripheral portion thereof;
measuring a thickness of the substrate after being ground, to acquire a thickness distribution of the substrate;
calculating, based on the thickness distribution, an optimal etching condition for optimizing an etching amount deviation distribution when etching the first surface; and
etching, under the optimal etching condition, the first surface of the substrate after being ground by supplying an etching liquid to the first surface from an etching liquid supply.

2. The substrate processing method of claim 1,
wherein a height of the recess portion is equal to or less than a difference between a maximum value and a minimum value of the etching amount deviation distribution allowed to be controlled when etching the first surface.

3. The substrate processing method of claim 2,
wherein the difference is determined based on an etching condition of the first surface.

4. The substrate processing method of claim 3,
wherein the difference is equal to or less than 1.0 μm.

5. The substrate processing method of claim 1,
wherein the recess portion and a flat portion provided in a ring shape around the recess portion are formed on the first surface after being ground, and
a diameter of the recess portion is equal to or less than a scan width when reciprocating the etching liquid supply in a diametric direction past a center of the first surface.

6. The substrate processing method of claim 5,
wherein the grinding of the first surface comprises:
grinding the first surface flat; and
further grinding a vicinity of the center of the first surface ground flat to form the recess portion.

7. The substrate processing method of claim 1,
wherein the optimizing of the etching amount deviation distribution is performed based on at least one of a rotation speed when rotating the substrate, a scan speed when reciprocating the etching liquid supply, or a scan width when reciprocating the etching liquid supply.

8. The substrate processing method of claim 1,
wherein the optimizing of the etching amount deviation distribution comprises:
acquiring etching amount deviation distributions of the first surface when etching the first surface under multiple different etching conditions; and
optimizing, such that the first surface has a target shape by superposing the etching amount deviation distributions corresponding to the multiple etching conditions, a combination of the etching amount deviation distributions used in superposition and a superposing number of the etching amount deviation distributions by using an optimization method.

9. The substrate processing method of claim 1,
wherein a second surface of the substrate is ground before the first surface is etched.

10. The substrate processing method of claim 9, further comprising:
calculating, based on the thickness distribution, an additional optimal etching condition for optimizing an etching amount deviation distribution when etching the second surface; and
etching, under the additional optimal etching condition, the second surface after being ground.

11. The substrate processing method of claim 1,
wherein before the first surface is etched, a second surface of the substrate is ground to form a recess portion whose center is more depressed than an outer peripheral portion thereof.

12. The substrate processing method of claim 1, further comprising:
grinding a second surface of the substrate before the first surface is etched,
wherein the grinding of the second surface and the grinding of the first surface are performed on multiple substrates consecutively, and
etching of the second surface is performed under a same etching condition on the multiple substrates.

13. A substrate processing system of processing a substrate, comprising:
a processing device configured to grind a first surface of the substrate to form, on the first surface, a recess portion whose center is more depressed than an outer peripheral portion thereof;
a thickness measuring device configured to measure a thickness of the substrate;
an etching device configured to etch the first surface by supplying an etching liquid to the first surface from an etching liquid supply; and
a control device,
wherein the control device executes a control of:
acquiring a thickness distribution of the substrate from the thickness of the substrate after being ground, which is measured by the thickness measuring device;
calculating, based on the thickness distribution, an optimal etching condition for optimizing an etching amount deviation distribution when etching the first surface; and
etching the first surface of the substrate under the optimal etching condition by using the etching device.

14. The substrate processing system of claim 13,
wherein control device controls a height of the recess portion to be equal to or less than a difference between a maximum value and a minimum value of the etching amount deviation distribution allowed to be controlled when etching the first surface.

15. The substrate processing system claim 14,
wherein the control device determines the difference based on an etching condition of the first surface.

16. The substrate processing system of claim 13,
wherein the control device executes a control of forming, on the first surface after being ground, the recess portion and a flat portion by using the processing device, the flat portion being provided in a ring shape around the recess portion, and
the control device sets a diameter of the recess portion to be equal to or less than a scan width when reciprocating the etching liquid supply in a diametric direction past a center of the first surface.

17. The substrate processing system of claim 16,
wherein the control device performs, by using the processing device, a control of:
grinding the first surface flat; and
further grinding a vicinity of the center of the first surface ground flat to form the recess portion.

18. The substrate processing system of claim 13,
wherein the control device performs the optimizing of the etching amount deviation distribution based on at least one of a rotation speed when rotating the substrate, a scan speed when reciprocating the etching liquid supply, or a scan width when reciprocating the etching liquid supply.

19. The substrate processing system of claim 13,
wherein when the optimizing of the etching amount deviation distribution is performed, the control device executes a control:
acquiring etching amount deviation distributions of the first surface when etching the first surface under multiple different etching conditions; and
optimizing, such that the first surface has a target shape by superposing the etching amount deviation distributions corresponding to the multiple etching conditions, a combination of the etching amount deviation distributions used in superposition and a superposing number of the etching amount deviation distributions by using an optimization method.
